(19) United States
(12) Patent Application Publication
(10) Pub. No.: US 2026/0156874 A1
(43) Pub. Date: Jun. 4, 2026

(54) SEMICONDUCTOR DEVICE AND MANUFACTURING METHOD THEREOF

(71) Applicant: Japan Display Inc., Tokyo (JP)

(72) Inventors: Akihiro HANADA, Tokyo (JP); Takuo KAITOH, Tokyo (JP); Motochika YUKAWA, Tokyo (JP); Hajime WATAKABE, Tokyo (JP)

(73) Assignee: Japan Display Inc., Tokyo (JP)

(21) Appl. No.: 19/404,048

(22) Filed: Dec. 1, 2025

(30) Foreign Application Priority Data
Dec. 2, 2024 (JP) 2024-209428
Sep. 29, 2025 (JP) 2025-162007

(51) Int. Cl. H10D 30/67; H10D 30/01

(52) U.S. Cl. CPC H10D 30/6757; H10D 30/0312; H10D 30/6734; H10D 30/6736; H10D 30/6756

(57) ABSTRACT

A semiconductor device includes a first gate electrode, a first insulating layer over the first gate electrode, a first oxide semiconductor layer over the first insulating layer, a second oxide semiconductor layer over and in contact with the first oxide semiconductor layer, a source electrode and a drain electrode in contact with each end surface of the first oxide semiconductor layer and the second oxide semiconductor layer, and a second insulating layer covering the source electrode and the drain electrode. The second oxide semiconductor layer includes a first region having a first film thickness and a second region having a second film thickness less than the first film thickness. An upper surface of the first region is in contact with one of the source electrode and the drain electrode, and an upper surface of the second region is in contact with the second insulating layer.

### CROSS-REFERENCE TO RELATED APPLICATIONS

This application claims the benefit of priority to Japanese Patent Application Nos. 2024-209428, filed on Dec. 2, 2024, and 2025-162007, filed on Sep. 29, 2025, the entire contents of each are incorporated herein by reference.

### FIELD

An embodiment of the present invention relates to a semiconductor device using an oxide semiconductor. Further, an embodiment of the present invention relates to a method for manufacturing a semiconductor device using an oxide semiconductor.

### BACKGROUND

In recent years, instead of a silicon semiconductor film using amorphous silicon, low-temperature polysilicon, and single-crystal silicon, a semiconductor device in which an oxide semiconductor film is used for a channel has been developed (for example, see Japanese laid-open patent publication Nos. 2021-141338, 2014-099601, 2021-153196, 2018-006730, 2016-184771, and 2021-108405). The transistor including an oxide semiconductor layer as a channel has a simple structure and can be manufactured by a low-temperature process, similar to a transistor including an amorphous silicon layer. Further, the transistor including an oxide semiconductor film is known to have a higher field effect mobility than the semiconductor device including an amorphous silicon film.

### SUMMARY

A semiconductor device according to an embodiment of the present invention includes a first gate electrode, a first insulating layer over the first gate electrode, a first oxide semiconductor layer over the first insulating layer, a second oxide semiconductor layer over and in contact with the first oxide semiconductor layer, a source electrode and a drain electrode in contact with each end surface of the first oxide semiconductor layer and the second oxide semiconductor layer, and a second insulating layer covering the source electrode and the drain electrode. The second oxide semiconductor layer includes a first region having a first film thickness and a second region having a second film thickness less than the first film thickness. An upper surface of the first region is in contact with one of the source electrode and drain electrode, and an upper surface of the second region is in contact with the second insulating layer.

A method for manufacturing a semiconductor device according to an embodiment of the present of the invention includes the steps of forming a first gate electrode over a substrate, forming a first insulating layer over the first gate electrode, depositing a first oxide semiconductor layer over the first insulating layer, depositing a second oxide semiconductor layer so as to contact with the first oxide semiconductor layer, collectively patterning the first oxide semiconductor layer and the second oxide semiconductor layer so that the first oxide semiconductor layer and the second oxide semiconductor layer have island shapes with substantially the same size, performing a heat treatment on the first oxide semiconductor layer and the second oxide semiconductor layer, forming a source electrode and a drain electrode in contact with each end surface of the first semiconductor layer and the second semiconductor layer, forming a first region having a first film thickness and forming a second region having a second film thickness smaller than the first film thickness in the second oxide semiconductor layer, and forming a second insulating layer covering the source electrode and the drain electrode. An upper surface of the first region is in contact with one of the source electrode and the drain electrode, and an upper surface of the second region is in contact with the second insulating layer.

### BRIEF DESCRIPTION OF DRAWINGS

FIG. 1 is a schematic cross-sectional view showing a configuration of a semiconductor device according to an embodiment of the present invention.

FIG. 2 is a schematic enlarged cross-sectional view showing a configuration of a semiconductor device according to an embodiment of the present invention.

FIG. 3 is a schematic plan view showing a configuration of a semiconductor device according to an embodiment of the present invention.

FIG. 4 is a schematic plan view showing a configuration of a semiconductor device according to an embodiment of the present invention.

FIG. 5 is a schematic plan view showing a configuration of a semiconductor device according to an embodiment of the present invention.

FIG. 6 is a flowchart illustrating a method for manufacturing a semiconductor device according to an embodiment of the present invention.

FIG. 7 is a schematic cross-sectional view illustrating a method for manufacturing a semiconductor device according to an embodiment of the present invention.

FIG. 8 is a schematic cross-sectional view illustrating a method for manufacturing a semiconductor device according to an embodiment of the present invention.

FIG. 9 is a schematic cross-sectional view illustrating a method for manufacturing a semiconductor device according to an embodiment of the present invention.

FIG. 10 is a schematic cross-sectional view illustrating a method for manufacturing a semiconductor device according to an embodiment of the present invention.

FIG. 11 is a schematic cross-sectional view illustrating a method for manufacturing a semiconductor device according to an embodiment of the present invention.

FIG. 12 is a schematic cross-sectional view illustrating a method for manufacturing a semiconductor device according to an embodiment of the present invention.

FIG. 13 is a schematic cross-sectional view illustrating a method for manufacturing a semiconductor device according to an embodiment of the present invention.

FIG. 14 is a schematic cross-sectional view illustrating a method for manufacturing a semiconductor device according to an embodiment of the present invention.

### DESCRIPTION OF EMBODIMENTS

In a semiconductor device having a so-called channel-etched structure in which an oxide semiconductor layer is etched when forming a source electrode and a drain electrode, desired electrical characteristics may not be obtained due to the influence of the etched back channel. Therefore, it is desired to suppress a decrease in a field effect mobility in a semiconductor device including an oxide semiconductor layer and having a channel-etched structure.

In view of the above problem, an embodiment of the present invention can suppress a decrease in a field effect mobility in a semiconductor device including an oxide semiconductor layer and having a channel-etched structure.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode over a semiconductor device.” On the other hand, the expression “a pixel electrode vertically over a transistor” means a positional relationship in which the semiconductor device and the pixel electrode overlap in a plan view. In addition, a plan view refers to viewing from a direction perpendicular to a surface of the substrate.

In the specification and the like, the expression “α includes A, B, or C,” “α includes any of A, B, or C,” “α includes one selected from a group consisting of A, B and C,” and the like does not exclude the case where α includes a plurality of combinations of A to C unless otherwise specified. Further, these expressions do not exclude the case where α includes other components.

In the present specification and the like, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, in the embodiments, although a liquid crystal display device including a liquid crystal layer and an organic EL display device including an organic EL layer are described as examples of display devices, structures described in the embodiments can be applied to the other display device including the electro-optical layers described above.

In the specification and the like, the terms “film” and “layer” can be optionally interchanged with one another.

The functions of a source electrode and a drain electrode of a transistor may be interchanged depending on the voltage supplied to each electrode. Therefore, in the present specification and the like, the terms “source electrode” and “drain electrode” may be interchanged in some cases. Similarly, in the specification and the like, the terms “source region” and “drain region” may be interchanged in some cases.

In addition, the following embodiments can be combined with each other as long as there is no technical contradiction.

### 1. Configuration of Semiconductor Device 10

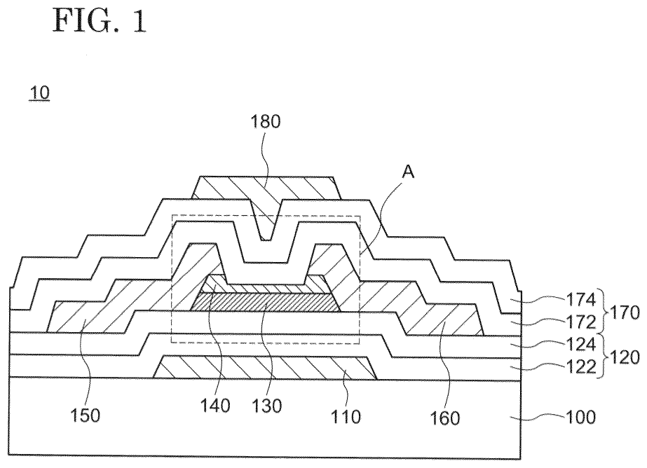

FIG. 1 is a schematic cross-sectional view showing a configuration of a semiconductor device 10 according to an embodiment of the present invention.

As shown in FIG. 1, the semiconductor device 10 includes a substrate 100, a first gate electrode 110, a first insulating layer 120, a first oxide semiconductor layer 130, a second oxide semiconductor layer 140, a source electrode 150, a drain electrode 160, a second insulating layer 170, and a second gate electrode 180. The first gate electrode 110 is provided on the substrate 100. The first insulating layer 120 is provided on the substrate 100 so as to cover the first gate electrode 110. The first oxide semiconductor layer 130 is provided on the first insulating layer 120 so as to overlap the first gate electrode 110. The second oxide semiconductor layer 140 is provided on the first oxide semiconductor layer 130 so as to overlap the first gate electrode 110. The source electrode 150 and the drain electrode 160 are in contact with the first oxide semiconductor layer 130 and the second oxide semiconductor layer 140 and are provided on the first insulating layer 120. The second insulating layer 170 is provided on the first insulating layer 120 so as to cover the first oxide semiconductor layer 130, the second oxide semiconductor layer 140, the source electrode 150, and the drain electrode 160. The second gate electrode 180 is provided on the second insulating layer 170 so as to overlap the first gate electrode 110, the first oxide semiconductor layer 130, and the second oxide semiconductor layer 140.

The first insulating layer 120 and the second insulating layer 170 can function as gate insulating layers. In the semiconductor device 10, the first gate electrode 110 is located below the first oxide semiconductor layer 130 and the second oxide semiconductor layer 140 with the first insulating layer 120 interposed therebetween, and the second gate electrode 180 is located over the first oxide semiconductor layer 130 and the second oxide semiconductor layer 140 with the second insulating layer 170 interposed therebetween. That is, the semiconductor device 10 is a so-called dual gate transistor. Different voltages may be applied to the first gate electrode 110 and the second gate electrode 180. Further, the first gate electrode 110 and the second gate electrode 180 may be electrically connected and the same voltage may be applied thereto.

Although the semiconductor device 10 shown in FIG. 1 is a dual gate transistor, a so-called bottom gate transistor in which only the first gate electrode 110 is located below the first oxide semiconductor layer 130 and the second oxide semiconductor layer 140 via the first insulating layer 120 can also be applied as the semiconductor device 10 in the present embodiment.

### 2. Components of Semiconductor Device 10

### [2-1. Substrate 100]

For example, a rigid substrate having light transmitting properties, such as a glass substrate, a quartz substrate, or a sapphire substrate, can be used as the substrate 100. Further, a rigid substrate having no light transmitting properties, such as a silicon substrate, can also be used as the substrate 100. Furthermore, a flexible substrate having light transmitting properties, such as a polyimide resin substrate, an acrylic resin substrate, a siloxane resin substrate, or a fluorine resin substrate, can also be used as the substrate 100. Impurities may be introduced into the flexible substrate in order to improve the heat resistance of the first substrate 100. In addition, the substrate 100 may be the above-described rigid or flexible substrate on which a silicon oxide film or a silicon nitride film is formed. Silicon oxide (SiOₓ), silicon oxynitride (SiOₓN_{y}), or the like can be used for the oxide insulating film. Silicon nitride (SiNₓ), silicon nitride oxide (SiNₓO_{y}), or the like can be used for the nitride insulating film. Here, SiOₓN_{y} is a silicon compound containing a smaller proportion of nitrogen (N) than oxygen (O) (x>y), and SiNₓO_{y} is a silicon compound containing a smaller proportion of oxygen than nitrogen (x>y).

### [2-2. First Gate Electrode 110 and Second Gate Electrode 180]

A metal material such as aluminum (Al), copper (Cu), titanium (Ti), molybdenum (Mo), tungsten (W), or an alloy thereof can be used for each of the first gate electrode 110 and the second gate electrode 180. Although the alloy can be molybdenum tungsten (MoW), for example, the alloy is not limited thereto. The first gate electrode 110 and the second gate electrode 180 can have a single layer structure or a stacked structure.

The first gate electrode 110 or the second gate electrode 180 can also function as a light shielding film. In this case, the first gate electrode 110 or the second gate electrode 180 preferably overlaps the entire first oxide semiconductor layer 130 and the entire second oxide semiconductor layer 140 in a plan view.

### [2-3. First Insulating Layer 120 and Second Insulating Layer 170]

Although each of the first insulating layer 120 and the second insulating layer 170 may have a single layer structure, it is preferable that each of the first insulating layer 120 and the second insulating layer 170 has a stacked structure. It is preferable that the first insulating layer 120 has a stacked structure in which an oxide insulating film 124 is stacked on a nitride insulating film 122. In this case, the nitride insulating film 122 is in contact with the first gate electrode 110, and the oxide insulating film 124 is in contact with the first oxide semiconductor layer 130. Further, it is preferable that the second insulating layer 170 has a stacked structure in which a nitride insulating film 174 is stacked on an oxide insulating film 172. In this case, the oxide insulating film 172 is in contact with end surfaces of the first oxide semiconductor layer 130 and end surfaces and a top surface of the second oxide semiconductor layer 140, and the nitride insulating film 174 is in contact with the second gate electrode 180. Silicon oxide (SiOₓ), silicon oxynitride (SiOₓN_{y}), or the like can be used for the oxide insulating films 124 and 172. Further, silicon nitride (SiNₓ) or silicon nitride oxide (SiNₓO_{y}) can be used for the nitride insulating films 122 and 174. For example, the film thickness of the first insulating layer 120 is greater than or equal to 100 nm and less than or equal to 900 nm, and preferably greater than or equal to 200 nm and less than or equal to 600 nm. When the first insulating layer 120 has such a large film thickness, the carrier concentration induced in the first oxide semiconductor layer 130 by the gate voltage of the first gate electrode 110 becomes small.

### [2-4. Source Electrode 150 and Drain Electrode 160]

The same metal material as the first gate electrode 110 and the second gate electrode 180 can be used for the source electrode 150 and the drain electrode 160. The source electrode 150 and the drain electrode 160 may have a single layer structure or a stacked-layer structure. The source electrode 150 and the drain electrode 160 are in contact with not only the first oxide semiconductor layer 130 but also the second oxide semiconductor layer 140.

### [2-5. First Oxide Semiconductor Layer 130 and Second Oxide Semiconductor Layer 140]

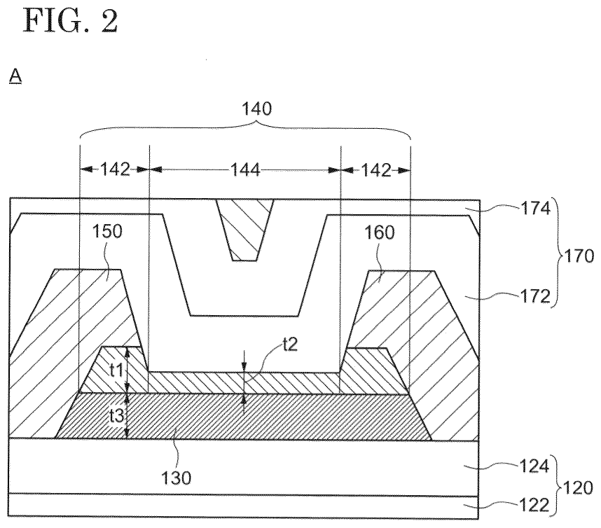

The semiconductor device 10 includes a stacked structure in which the second oxide semiconductor layer 140 is stacked on the first oxide semiconductor layer 130. Details of the stacked structure are described with reference to FIG. 2.

FIG. 2 is a schematic enlarged cross-sectional view showing a configuration of the semiconductor device 10 according to an embodiment of the present invention. Specifically, FIG. 2 is an enlarged cross-sectional view of the semiconductor device 10 in a region A in FIG. 1.

At least a portion of the end surface of each of the first oxide semiconductor layer 130 and the second oxide semiconductor layer 140 is covered by the source electrode 150 or the drain electrode 160. A recess is formed in the upper surface of the second oxide semiconductor layer 140, and the second oxide semiconductor layer 140 includes a first region 142 and a second region 144 having different film thicknesses. The first region 142 and the second region 144 have a first film thickness t1 and a second film thickness t2, respectively. The second film thickness t2 is smaller than the first film thickness t1. The upper surface of the first region 142 is in contact with and covered by the source electrode 150 or the drain electrode 160. The upper surface of the second region 144 is in contact with and covered by the second insulating layer 170 (more specifically, the oxide insulating film 172). In other words, the first region 142 overlaps the source electrode 150 or the drain electrode 160, and the second region 144 does not overlap the source electrode 150 or the drain electrode 160.

Although details are described later, the upper surface of the second oxide semiconductor layer 140 is etched to form the recess when the source electrode 150 and the drain electrode 160 are patterned. As a result, the second region 144 has a second film thickness t2 that is smaller than the first film thickness t1. For example, the first film thickness t1 corresponds to the thickness of the second oxide semiconductor layer 140 at the time of deposition. The first film thickness t1 is greater than or equal to 20 nm and less than or equal to 200 nm, preferably greater than or equal to 20 nm and less than or equal to 150 nm, and more preferably greater than or equal to 20 nm and less than or equal to 100 nm. When the first film thickness t1 is too small, the second region 144 disappears and the first oxide semiconductor layer 130 is exposed during patterning of the source electrode 150 and the drain electrode 160. When the first film thickness t1 is too large, it takes a long time not only to deposit the second oxide semiconductor layer 140 but also to pattern the second oxide semiconductor layer 140. The second film thickness t2 can be controlled by the overetching time when patterning the source electrode 150 and the drain electrode 160. The second film thickness t2 may be any thickness that sufficiently covers the upper surface of the first oxide semiconductor layer 130. For example, the second film thickness t2 is greater than 0 nm and less than or equal to 100 nm, preferably greater than or equal to 5 nm and less than or equal to 70 nm, and more preferably greater than or equal to 5 nm and less than or equal to 50 nm. When the second film thickness t2 is too large, oxygen deficiencies in the second region 144 cannot be sufficiently repaired, so that the conductivity of the second region 144 becomes high.

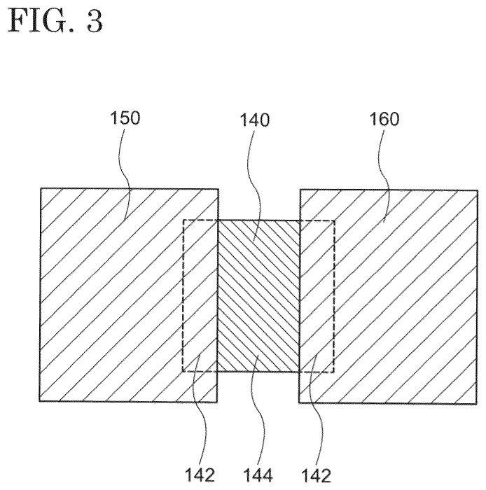

FIGS. 3 to 5 are schematic plan views showing a configuration of the semiconductor device according to an embodiment of the present invention. Specifically, FIGS. 3 to 5 shows the second oxide semiconductor layer 140, and the source electrode 150 and the drain electrode 160 overlapping the second oxide semiconductor layer 140.

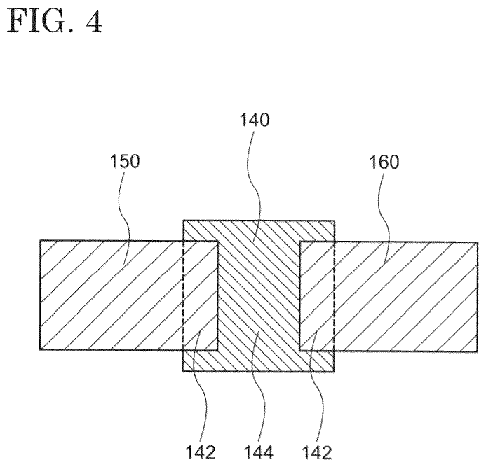

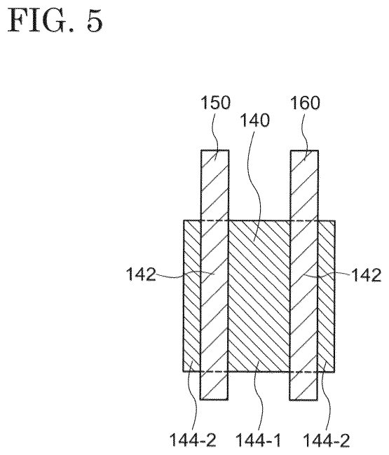

Each of the source electrode 150 and the drain electrode 160 may be formed so as to completely cover one side of the second oxide semiconductor layer 140 (see FIG. 3). In this case, the second region 144 is formed between the source electrode 150 and the drain electrode 160 (i.e., between two first regions 142). Further, each of the source electrode 150 and the drain electrode 160 may be formed so as to cover a part of one side of the second oxide semiconductor layer 140 (see FIG. 4). In this case, the second region 144 is formed not only between the source electrode 150 and the drain electrode 160 (i.e., between two first regions 142), but also around the source electrode 150 and the drain electrode 160. Furthermore, the source electrode 150 and the drain electrode 160 may be formed so as to form a plurality of second regions 144-1 and 144-2 (see FIG. 5). In this case, the second region 144-1 is formed between the source electrode 150 and the drain electrode 160 (i.e., between the two first regions 142), and the second region 144-2 is formed outside each of the source electrode 150 and the drain electrode 160.

The first oxide semiconductor layer 130 contains indium (in).

The second oxide semiconductor layer 140 also preferably contains indium. However, the proportion of indium to all metal elements in the second oxide semiconductor layer 140 is lower than the proportion of indium to all metal elements in the first oxide semiconductor layer 130. Further, the second oxide semiconductor layer 140 preferably contains a metal element that is not contained in the first oxide semiconductor layer 130.

The third film thickness t3 of the first oxide semiconductor layer 130 is not limited to a certain value. For example, the third film thickness t3 is greater than or equal to 15 nm and less than or equal to 150 nm, preferably greater than or equal to 15 nm and less than or equal to 125 nm, and more preferably greater than or equal to 15 nm and less than or equal to 100 nm. When the third film thickness t3 is too large, oxygen deficiencies in the first oxide semiconductor layer 130 may not be reduced, and desired electrical characteristics may not be obtained.

It is preferable that the third film thickness t3 is larger than the second film thickness t2. When the third film thickness t3 is larger than the second film thickness t2, a main channel is formed in the first oxide semiconductor layer 130, thereby increasing the field effect mobility. Further, the third film thickness t3 may be smaller than the first film thickness t1. Alternatively, the third film thickness t3 may be greater than or equal to the difference in film thickness between the first film thickness t1 and the second film thickness t2. In this case, the number of electrons injected from the source electrode 150 into the first region 142 increases and flows through the first oxide semiconductor layer 130, thereby increasing the field effect mobility.

A transistor in which the top surface of the oxide semiconductor layer (sometimes referred to as the back channel) is etched is called a channel-etched transistor. That is, when the second oxide semiconductor layer 140, which has a lower indium content than the first oxide semiconductor layer 130, is provided on the back channel side of the first oxide semiconductor layer 130 in the semiconductor device 10, the influence of the back channel can be reduced and a decrease in field effect mobility can be suppressed.

### 3. Manufacturing Method of Semiconductor Device 10

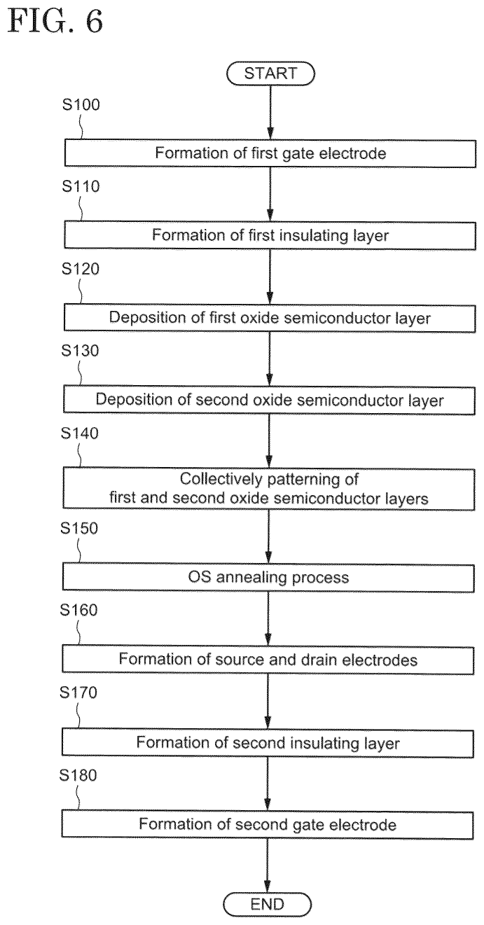

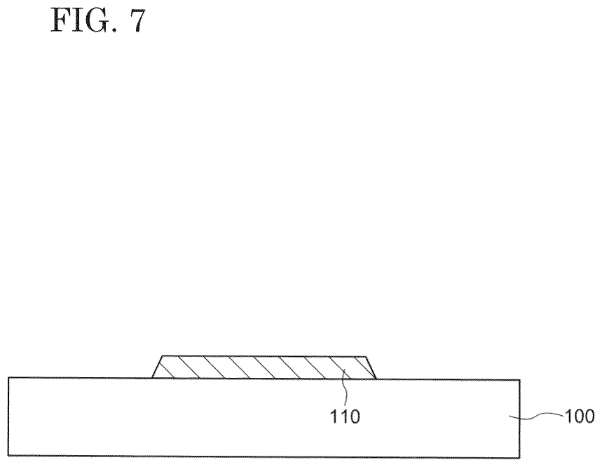

FIG. 6 is a flowchart illustrating a method for manufacturing the semiconductor device 10 according to an embodiment of the present invention. FIGS. 7 to 14 are schematic cross-sectional views illustrating a method for manufacturing the semiconductor device 10 according to an embodiment of the present invention. Hereinafter, each step of the flowchart shown in FIG. 6 is described in order.

In step S100, the first gate electrode 110 is formed on the substrate 100 (see FIG. 7). The first gate electrode 110 is formed by depositing a conductive film by sputtering and then patterning the conductive film into a predetermined shape using photolithography.

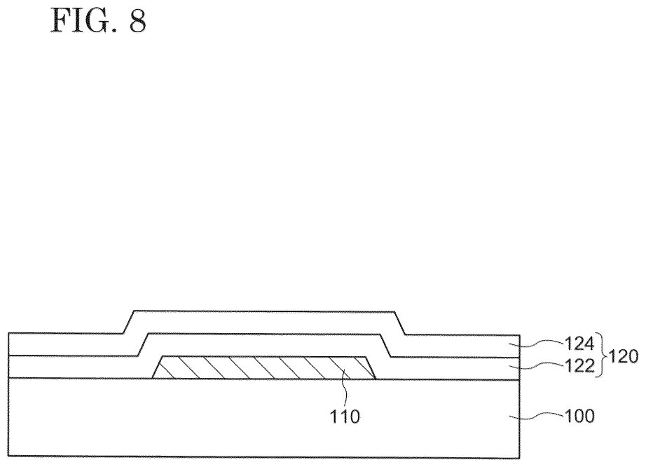

In step S110, the first insulating layer 120 is formed on the first gate electrode 110 (see FIG. 8). When the first insulating layer 120 has a stacked structure, the first insulating layer 120 is formed by depositing the nitride insulating film 122 and the oxide insulating film 124 by CVD.

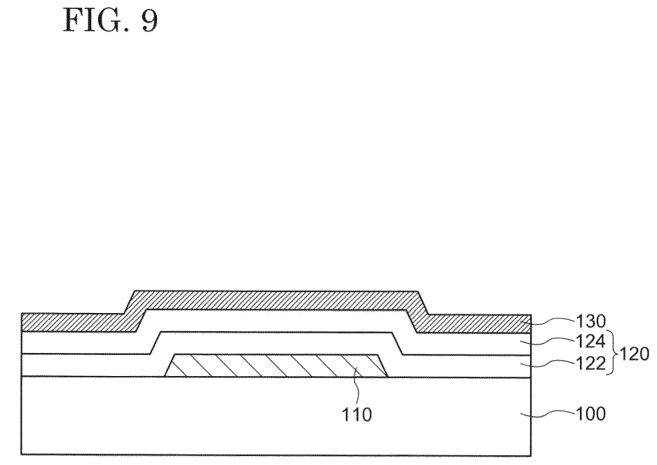

In step S120, the first oxide semiconductor layer 130 is deposited on the first insulating layer 120 (see FIG. 9). The first oxide semiconductor layer 130 is deposited by sputtering.

When a film is formed on an object by sputtering, ions generated in the plasma and atoms recoiled from the sputtering target collide with the object, so that the temperature of the object rises during the film formation process.

In the sputtering process, the first oxide semiconductor layer 130 having an amorphous structure is deposited under conditions of an oxygen partial pressure less than or equal to 10%.

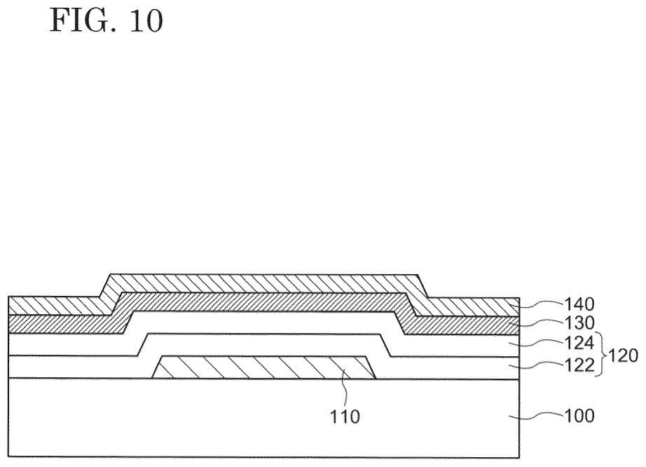

In step S130, the second oxide semiconductor layer 140 is deposited on the first oxide semiconductor layer 130 (see FIG. 10). The second oxide semiconductor layer 140 is deposited by sputtering.

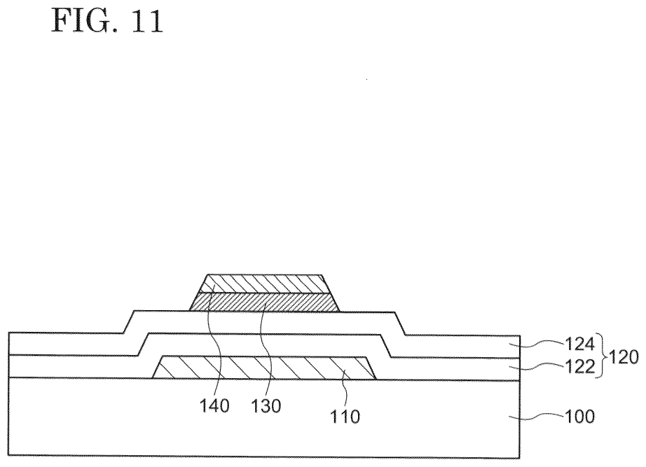

In step S140, the first oxide semiconductor layer 130 and the second oxide semiconductor layer 140 are patterned collectively (see FIG. 11). The first oxide semiconductor layer 130 and the second oxide semiconductor layer 140 are formed to have a stacked structure in an island shape using photolithography. For example, a resist mask (not shown in figures) is formed on the second oxide semiconductor layer 140, and the second oxide semiconductor layer 140 and the first oxide semiconductor layer 130 are sequentially etched using the resist mask. As a result, the first oxide semiconductor layer 130 and the second oxide semiconductor layer 140 have island shapes of approximately the same size. The first oxide semiconductor layer 130 and the second oxide semiconductor layer 140 may be etched by wet etching or dry etching. For wet etching, an acidic etching solution may be used. For example, oxalic acid, PAN, sulfuric acid, hydrogen peroxide, and hydrofluoric acid can be used for an etching solution.

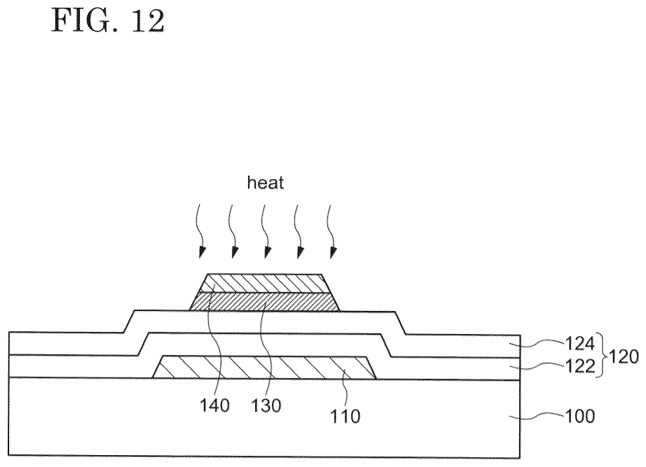

In step S150, a heat treatment (OS annealing process) is performed on the first oxide semiconductor layer 130 and the second oxide semiconductor layer 140 (see FIG. 12). In the OS annealing process, the first oxide semiconductor layer 130 and the second oxide semiconductor layer 140 are held at a predetermined reaching temperature for a predetermined time. The predetermined reaching temperature is higher than or equal to 300° C. and lower than or equal to 500° C., preferably higher than or equal to 350° C. and lower than or equal to 450° C. The holding time at the reaching temperature is greater than or equal to 15 minutes and less than or equal to 120 minutes, preferably greater than or equal to 30 minutes and less than or equal to 60.

The proportion of indium to all metal elements in the second oxide semiconductor layer 140 is lower than the proportion of indium to all metal elements in the first oxide semiconductor layer 130.

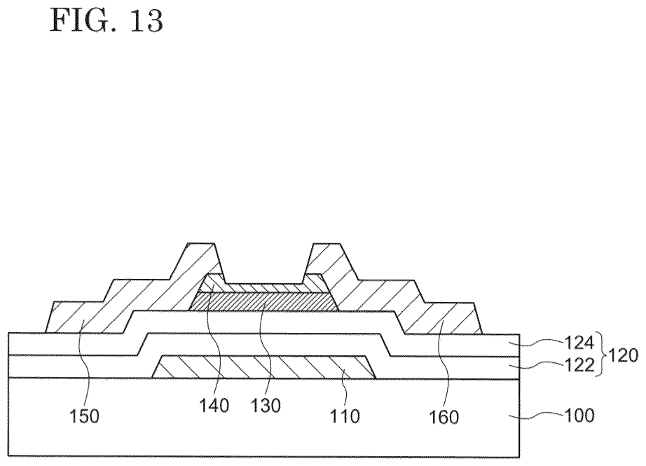

In step S160, the source electrode 150 and the drain electrode 160 are formed so as to be in contact with the first oxide semiconductor layer 130 and the second oxide semiconductor layer 140 (see FIG. 13). The source electrode 150 and the drain electrode 160 are formed by depositing a conductive film by sputtering and then patterning the conductive film into a predetermined shape using photolithography. The source electrode 150 and the drain electrode 160 may be etched by wet etching or dry etching. When the source electrode 150 and the drain electrode 160 are etched, the upper surface of the second oxide semiconductor layer 140 is also etched to form the recess. That is, the first region 142 overlapping the source electrode 150 or the drain electrode 160 and the second region 144 not overlapping the source electrode 150 or the drain electrode 160 are formed in the second oxide semiconductor layer 140. Since the second region 144 corresponds to the region where the recess is formed, the second film thickness t2 of the second region 144 is smaller than the first film thickness t1 of the first region 142 (see FIG. 2).

Many defects are generated on the upper surface of the second region 144 by etching the source electrode 150 and the drain electrode 160. This is more pronounced when dry etching is used. The resist mask formed when the patterning the source electrode 150 and the drain electrode 160 is removed by a remover. At this time, the upper surface of the second region 144 is exposed to the remover. The remover can etch the oxide semiconductor contained in the second oxide semiconductor layer 140. Therefore, in step S160, even when many defects are generated on the upper surface of the second region 144, the remover can etch the region near the surface containing many defects. Accordingly, defects on the upper surface of the second region 144, i.e., in the back channel, can be reduced in the semiconductor device 10.

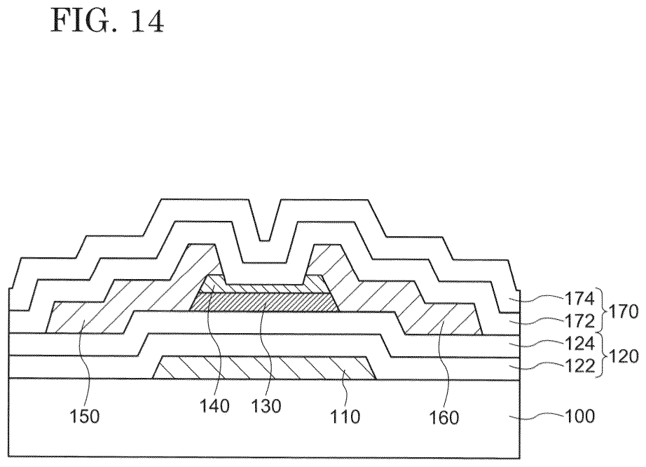

In step S170, the second insulating layer 170 is formed on the source electrode 150 and the drain electrode 160 (see FIG. 14). When the second insulating layer 170 has a stacked structure, the second insulating layer 170 is formed by depositing the oxide insulating film 172 and the nitride insulating film 174 by CVD.

In addition, in step S170, the heat treatment (oxidation annealing process) is preferably performed in a state in which the second insulating layer 170 covers the first oxide semiconductor layer 130 and the second oxide semiconductor layer 140. The oxidation annealing process can repair oxygen deficiencies in the first oxide semiconductor layer 130 and the second oxide semiconductor layer 140. In particular, in the oxidation annealing process, when the oxide insulating film 172 is in contact with the second region 144 of the second oxide semiconductor layer 140, oxygen is supplied from the oxide insulating film 172 to the second region 144, so that oxygen deficiencies in the back channel can be efficiently repaired. In step S170, the oxidation annealing process may be performed after the oxide insulating film 172 is formed, and then the nitride insulating film 174 may be deposited.

The oxidation annealing process may be performed with a metal oxide film formed on the oxide insulating film 172. When the metal oxide film is formed, oxygen released from the oxide insulating film 172 can be prevented from being released to the outside. The metal oxide film is removed after the oxidation annealing process. Aluminum oxide (AlOₓ), indium tin oxide (ITO), indium zinc oxide (IZO), indium gallium zinc oxide (IGZO), or the like can be used for the metal oxide film. For example, the film thickness of the metal oxide film is greater than or equal to 1 nm and less than or equal to 50 nm, and preferably greater than or equal to 1 nm and less than or equal to 30 nm.

In step S180, the second gate electrode 180 is formed on the second insulating layer 170. The second gate electrode 180 is deposited by depositing a conductive film by sputtering and then patterning the conductive film into a predetermined shape using photolithography.

The semiconductor device 10 shown in FIG. 1 can be manufactured through the steps described above.

In the present embodiment, it is possible to suppress a decrease in a field effect mobility of the semiconductor device 10 including the oxide semiconductor layer and having a channel-etched structure. Further, variations in the electrical characteristics of the semiconductor device 10 can be reduced, and the manufacturing yield of the semiconductor device 10 can be improved.

Each of the embodiments and modifications described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments and modifications are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device, comprising:
a first gate electrode;
a first insulating layer over the first gate electrode;
a first oxide semiconductor layer over the first insulating layer;
a second oxide semiconductor layer over and in contact with the first oxide semiconductor layer;
a source electrode and a drain electrode in contact with each end surface of the first oxide semiconductor layer and the second oxide semiconductor layer; and
a second insulating layer covering the source electrode and the drain electrode,
wherein the second oxide semiconductor layer comprises:
a first region having a first film thickness, and
a second region having a second film thickness less than the first film thickness,
wherein an upper surface of the first region is in contact with one of the source electrode and the drain electrode, and
wherein an upper surface of the second region is in contact with the second insulating layer.

2. The semiconductor device according to claim 1, wherein the second oxide semiconductor layer has an amorphous structure.

3. The semiconductor device according to claim 1, wherein the first oxide semiconductor layer has a third film thickness, and wherein the third film thickness is greater than the second film thickness.

4. The semiconductor device according to claim 3, wherein the third film thickness is less than the first film thickness.

5. The semiconductor device according to claim 3, wherein the third film thickness is greater than or equal to a film thickness difference between the first film thickness and the film second thickness.

6. The semiconductor device according to claim 1,
wherein each of the first oxide semiconductor layer and the second oxide semiconductor layer comprises indium, and
wherein a ratio of the indium to all metal elements in the second oxide semiconductor layer is less than a ratio of the indium to all metal elements in the first oxide semiconductor layer.

7. The semiconductor device according to claim 1, further comprising a second gate electrode over the second insulating layer.

8. The semiconductor device according to claim 7,
wherein the second insulating layer has a stacked structure in which an oxide insulating film and a nitride insulating film are stacked,
wherein the oxide insulating film is in contact with the second oxide semiconductor layer, and
wherein the nitride insulating film is in contact with the second gate electrode.

9. A method for manufacturing a semiconductor device, comprising the steps of:
forming a first gate electrode over a substrate;
forming a first insulating layer over the first gate electrode;
depositing a first oxide semiconductor layer over the first insulating layer;
depositing a second oxide semiconductor layer in contact with the first oxide semiconductor layer;
collectively patterning the first oxide semiconductor layer and the second oxide semiconductor layer so that the first oxide semiconductor layer and the second oxide semiconductor layer have island shapes with substantially a same size;
performing a heat treatment on the first oxide semiconductor layer and the second oxide semiconductor layer;
forming a source electrode and a drain electrode in contact with each end surface of the first semiconductor layer and the second semiconductor layer, wherein a first region having a first film thickness and a second region having a second film thickness less than the first film thickness are formed in the second oxide semiconductor layer; and
forming a second insulating layer so as to cover the source electrode and the drain electrode,
wherein an upper surface of the first region is in contact with one of the source electrode and the drain electrode, and
wherein an upper surface of the second region is in contact with the second insulating layer.

10. The method for manufacturing a semiconductor device according to claim 9, wherein the second oxide semiconductor layer has an amorphous structure.

11. The method for manufacturing a semiconductor device according to claim 9,
wherein the first oxide semiconductor layer has a third film thickness, and
wherein the third film thickness is greater than the second film thickness.

12. The method for manufacturing a semiconductor device according to claim 11, wherein the third film thickness is less than the first film thickness.

13. The method for manufacturing a semiconductor device according to claim 11, wherein the third film thickness is greater than or equal to a film thickness difference between the first film thickness and the second film thickness.

14. The method for manufacturing a semiconductor device according to claim 9,
wherein each of the first oxide semiconductor layer and the second oxide semiconductor layer comprises indium, and
wherein a ratio of the indium to all metal elements in the second oxide semiconductor layer is less than a ratio of the indium to all metal elements in the first oxide semiconductor layer.

15. The method for manufacturing a semiconductor device according to claim 9, further comprising a step of forming a second gate electrode over the second insulating layer.

16. The method for manufacturing a semiconductor device according to claim 15,
wherein the second insulating layer has a stacked structure in which an oxide insulating film and a nitride insulating film are stacked,
wherein the oxide insulating film is in contact with the second oxide semiconductor layer, and
wherein the nitride insulating film is in contact with the second gate electrode.
